(19) United States
(12) Patent Application Publication
(10) Pub. No.: US 2024/0417850 A1
(43) Pub. Date: Dec. 19, 2024

(54) METHOD AND APPARATUS FOR MAKING A VAPOR OF PRECISE CONCENTRATION BY SUBLIMATION

(71) Applicant: CeeVee Tech, LLC, Peabody, MA (US)

(72) Inventor: Egbert G. WOELK, North Andover, MA (US)

(21) Appl. No.: 18/817,485

(22) Filed: Aug. 28, 2024

Related U.S. Application Data
(63) Continuation-in-part of application No. 17/493,278, filed on Oct. 4, 2021, now Pat. No. 12,104,252.
Application No. 17/493,278 is a continuation-in-part of application No. 16/260,378, filed on Jan. 29, 2019, now Pat. No. 11,168,394.
Application No. 17/493,278 is a continuation-in-part of application No. 17/227,695, filed on Apr. 12, 2021, now Pat. No. 11,965,243.
Application No. 17/227,695 is a continuation of application No. 16/260,378, filed on Jan. 29, 2019, now Pat. No. 11,168,394.
(60) Provisional application No. 62/642,982, filed on Mar. 14, 2018.
(60) Provisional application No. 62/642,982, filed on Mar. 14, 2018.

(51) Int. Cl. C23C 16/448; C23C 16/46; C23C 16/52; C23C 18/12

(52) U.S. Cl. CPC C23C 16/4481; C23C 16/46; C23C 16/52; C23C 16/448; C23C 18/1283

(57) ABSTRACT

Techniques for controlling a solid precursor vapor source are provided. An example method of controlling a solid precursor vapor source includes providing a carrier gas to a sublimation vessel containing a solid precursor material, and the carrier gas is configured to flow over a surface of the precursor material (advective flow source), wherein the carrier gas is heated with a carrier gas temperature control device prior to entering the sublimation vessel, measuring a temperature of a vapor exiting the sublimation vessel, and controlling a temperature of the carrier gas with the carrier gas temperature control device based at least in part on the temperature of the vapor exiting the sublimation vessel.

### CROSS-REFERENCE TO RELATED APPLICATIONS

This application is a continuation-in-part of U.S. patent application Ser. No. 17/493,278, filed on Oct. 4, 2021, entitled “METHOD AND APPARATUS FOR MAKING A VAPOR OF PRECISE CONCENTRATION BY SUBLIMATION,” which is a continuation-in-part of U.S. patent application Ser. No. 16/260,378, now U.S. Pat. No. 11,168,394, filed on Jan. 29, 2019, entitled “METHOD AND APPARATUS FOR MAKING A VAPOR OF PRECISE CONCENTRATION BY SUBLIMATION,” which claims the benefit of U.S. Provisional Application No. 62/642,982, filed Mar. 14, 2018, entitled “METHOD AND APPARATUS FOR MAKING A VAPOR OF PRECISE CONCENTRATION BY SUBLIMATION,” and U.S. patent application Ser. No. 17/493,278 is also a continuation-in-part of U.S. patent application Ser. No. 17/227,695, now U.S. Pat. No. 11,965,243, filed Apr. 12, 2021, entitled “METHOD AND APPARATUS FOR MAKING A VAPOR OF PRECISE CONCENTRATION BY SUBLIMATION,” which is a continuation of U.S. patent application Ser. No. 16/260,378, now U.S. Patent No. 11, 168,394, filed on Jan. 29, 2019, entitled “METHOD AND APPARATUS FOR MAKING A VAPOR OF PRECISE CONCENTRATION BY SUBLIMATION,” which claims the benefit of U.S. Provisional Application No. 62/642,982, filed Mar. 14, 2018, entitled “METHOD AND APPARATUS FOR MAKING A VAPOR OF PRECISE CONCENTRATION BY SUBLIMATION,” of which is assigned to the assignee hereof, and the entire contents of each of which are hereby incorporated herein by reference for all purposes.

### BACKGROUND

A chemical vapor deposition (CVD) process generally depends on the controlled evaporation of a liquid or solid precursor. Suitable liquid and solid precursors have a reasonably high vapor pressure. The vapor of the precursor is generated by flowing a carrier gas through the precursor inside an evaporation (sublimation for a solid precursor) vessel. The resulting vapor output is transported to the process chamber where the precursor reacts on the surface of a substrate to form a material film. For nearly all processes the delivery rate of the precursor (in grams per second, for example) needs to be precisely controlled in order to make the desired material film. The sublimation determines the vapor concentration which is the ratio of the partial pressure of the precursor to the total pressure (vapor plus carrier gas) at the outlet of the sublimation vessel. The delivery rate of precursor to the CVD process is determined by the flow rate of the vapor and its concentration. Thus, the control of the evaporation or sublimation (in case of a solid) is critical for the CVD process to produce the desired material film.

### SUMMARY

An example of a solid precursor vapor source according to the disclosure includes a sublimation vessel configured to contain a bed of a precursor material, such that the sublimation vessel includes one or more thermally insulated exterior walls, an inlet port disposed at a first side of the bed of the precursor material and configured to enable a flow of a carrier gas into the sublimation vessel, a first temperature control device disposed proximate to the inlet port and configured to control a temperature of the carrier gas entering the sublimation vessel, an outlet port disposed at a second side of the bed of the precursor material and configured to enable a flow of an entrained vapor to exit the sublimation vessel, such that the entrained vapor is generated by the carrier gas flowing in close proximity to or through the bed of the precursor material from the first side to the second side, a second temperature control device disposed proximate to the outlet port and configured to control a temperature of the carrier gas and the entrained vapor exiting the sublimation vessel, a first temperature sensor disposed in the sublimation vessel proximate to the first side of the bed of the precursor material, a second temperature sensor disposed in the sublimation vessel proximate to the second side of the bed of the precursor material, a control computer operably coupled to the first temperature control device, the second temperature control device, the first temperature sensor and the second temperature sensor, and configured to control the first temperature control device based on a first temperature value sensed by the first temperature sensor, and control the second temperature control device based on a second temperature value sensed by the second temperature sensor, such that the second temperature value is approximately a sublimation temperature of the precursor material and the first temperature value is higher than the second temperature value.

Implementations of such a solid precursor vapor source may include one or more of the following features. A pressure controller may be operably coupled to the control computer, such that the pressure controller is disposed on the outlet port and is configured to measure and control a sublimation vessel pressure value Pₛᵥ. The control computer may be configured to control the first temperature control device such that the first temperature value is approximately equal to the sublimation temperature of the precursor material plus a delta temperature value, such that the delta temperature value is based at least in part on the sublimation vessel pressure value Pₛᵥ, a heat of sublimation value of the precursor material, and a specific heat at constant pressure (cp) value of the carrier gas. A mass flow controller may be operably coupled to the control computer and configured to control the flow of the carrier gas into the sublimation vessel through the inlet port. A carrier gas thermal device may be operably coupled to the control computer and disposed proximate to the inlet port of the sublimation vessel, such that the control computer is configured to control the carrier gas thermal device based at least in part on the first temperature value and the second temperature value. A temperature sensing tube may be disposed in the sublimation vessel, such that the first temperature sensor and the second temperature sensor are attached to the temperature sensing tube. A turbulator may be disposed in the sublimation vessel between the inlet port and the first side of the bed of the precursor material and configured to diffuse the carrier gas over the first side of the bed of the precursor material. The turbulator may be a plate comprising a plurality of structures extending outward from the plate. The first temperature control device and the second temperature control device may include a thermoelectric cooler and a resistive heater. The one or more thermally insulated exterior walls may be a thermally isolating shroud disposed around at least a portion of the sublimation vessel.

An example of a method for controlling a solid precursor vapor source according to the disclosure includes providing a carrier gas to a precursor material in a sublimation vessel, such that the sublimation vessel includes an inlet area and an outlet area configured to enable the carrier gas to flow through the precursor material, and at least one thermal device configured to add or remove heat from the sublimation vessel, determining a sublimation temperature value and a delta temperature value (ΔT) based on the material properties of the precursor material and the carrier gas, the vessel pressure value Pₛᵥ, and the value of the outlet temperature sensor, setting a first temperature in the sublimation vessel based on the sublimation temperature value and the delta temperature value, such that the first temperature is measured proximate to the inlet area, and setting a second temperature in the sublimation vessel based on the sublimation temperature value, such that the second temperature is measured proximate to the outlet area.

Implementations of such a method may include one or more of the following features. The delta temperature value may be based on a heat of sublimation value of the precursor material, a specific heat at constant pressure (cₚ) value of the carrier gas, a vapor pressure value of the precursor material at the sublimation temperature value, and a sublimation vessel pressure value Pₛᵥ. Setting the first temperature and the second temperature may include setting a carrier gas thermal device temperature. Setting the first temperature and the second temperature may include setting an upstream thermal device temperature. Setting the second temperature may include setting a downstream thermal device. Determining the sublimation temperature value and the delta temperature value may include receiving the sublimation temperature value and the delta temperature value from a networked computer.

An example of a method of controlling a solid precursor vapor source according to the disclosure includes providing a carrier gas to a carrier gas thermal device configured to control a temperature of the carrier gas prior to entering a sublimation vessel, such that a pressure of the sublimation vessel is controlled by a pressure control device, providing the carrier gas to a precursor material in the sublimation vessel, such that the sublimation vessel includes an inlet area and an outlet area configured to enable the carrier gas to flow through the precursor material, measuring an inlet carrier gas temperature and an outlet carrier gas temperature for the carrier gas flowing through the respective inlet area and the outlet area of the sublimation vessel, determining a compensated sublimation vessel pressure value P_{svc} based on the outlet carrier gas temperature, the vapor pressure curve associated with the precursor material, determining a delta temperature value based at least in part on the precursor material, the carrier gas, and the compensated sublimation vessel pressure value P_{svc}, and providing a temperature control signal to the carrier gas thermal device based on the delta temperature value and the outlet gas temperature value.

Implementations of such a method may include one or more of the following features. Determining the compensated sublimation vessel pressure value P_{svc} may include receiving a nominal (or recipe) temperature value for a chemical vapor deposition process, receiving a nominal (or recipe) sublimation vessel pressure value Pₛᵥ for a chemical vapor deposition process, and determining the compensated sublimation vessel pressure based on a ratio of a vapor pressure value of the precursor material at the nominal temperature and the vapor pressure value of the precursor material at the outlet gas temperature.

An example of a controller for a solid precursor vapor source includes a memory unit, at least one processor operably coupled to the memory unit and configured to receive a plurality of system values including a nominal sublimation temperature value, a cp value for a carrier gas, a heat of sublimation value for a precursor material, the parameter values for a vapor pressure curve for the precursor material, and a nominal (or recipe) sublimation vessel pressure value Pₛᵥ, receive a downstream second temperature value based on a downstream second temperature sensor, calculate a downstream error value equal to a difference between the downstream second temperature value and the nominal sublimation temperature value, calculate a downstream output value based on the downstream error value, provide a control signal to a downstream pressure control device based on the downstream output value, such that the control signal is configured to make the sublimation vessel pressure value equal the compensated sublimation vessel pressure value, calculate a delta-temperature value based on the cp value for the carrier gas, the heat of sublimation value for the precursor material, a vapor pressure value based on the sublimation temperature value, and the sublimation vessel pressure value, receive an upstream first temperature value based on a upstream first temperature sensor, calculate an upstream first error value equal to the downstream second temperature value plus the delta-temperature value minus the upstream first temperature value, calculate an upstream output value based on the upstream first error value, and provide a control signal to an upstream first thermal device based on the upstream first output value, such that the control signal is configured to change a temperature of the upstream first thermal device to make the upstream first temperature value equal to the sublimation downstream second temperature value plus the delta-temperature value.

Items and/or techniques described herein may provide one or more of the following capabilities, as well as other capabilities not mentioned. System variables associated with a chemical vapor deposition process may be provided to a controller. The controller may be configured to sense temperatures within a solid precursor sublimation vessel. The sublimation vessel may have one or more thermal devices configured to control the temperature of a carrier gas flowing through a precursor bed. The controller may be operably coupled to the thermal devices can configured to send control signals based on the temperatures within the sublimation vessel. The sublimation vessel may be insulated. Pressure and flow devices may be disposed on the inlet and/or outlet of the sublimation vessel. The controller may be operably coupled to the pressure and flow devices and configured to control the pressure and carrier gas flow rate through the precursor bed. Other capabilities may be provided and not every implementation according to the disclosure must provide any, let alone all, of the capabilities discussed. Further, it may be possible for an effect noted above to be achieved by means other than that noted, and a noted item/technique may not necessarily yield the noted effect.

### BRIEF DESCRIPTION OF THE DRAWINGS

FIG. 1A is a diagram of a temperature distribution in a bed of a solid precursor at respective low and high carrier gas flows that are percolating through the solid precursor.

FIG. 1B is a diagram of a temperature distribution in a bed of a solid precursor with an advective flow of carrier gas over the precursor bed.

FIG. 2A is a system diagram of an example sublimation vessel for solid bed precursors with a percolating carrier gas flow.

FIG. 2B is a system diagram of an example sublimation vessel for solid bed precursors with a advective carrier gas flow over the precursor bed.

FIG. 3A is a system diagram of an example percolation solid precursor vapor source.

FIG. 3B is a system diagram of an example advection solid precursor vapor source.

FIG. 4 is a flow diagram of an example method for controlling a solid precursor vapor source.

FIG. 5 is a flow diagram of an example process for controlling downstream and upstream thermal devices in a solid precursor vapor source.

FIG. 6A is a drawing of an embodiment of an advection solid precursor vapor source with multiple flow paths

FIG. 6B is the diagram of multiple baffles defining multiple flow paths

### DETAILED DESCRIPTION

Techniques are discussed herein for controlling the concentration of a vapor of a chemical compound in a carrier gas that is generated by the sublimation of a solid precursor. For example, a chemical vapor deposition (CVD) process generally depends on the controlled evaporation of a liquid or solid precursor. Suitable liquid and solid precursors have a reasonably high vapor pressure. The vapor of the precursor is transported in a carrier gas to the process chamber where the precursor reacts on the surface of a substrate to form a material film. For nearly all processes the delivery rate of the precursor (in grams per second, for example) needs to be precisely controlled in order to make the desired material film. The evaporation determines the delivery rate. Thus the control of the evaporation or sublimation (in case of a solid) is critical for the CVD process to produce the desired material film. The concentration c of the precursor compound in the carrier gas is the ratio of the partial pressure of the precursor to the total pressure (vapor plus carrier gas) at the output of the sublimation vessel or c=(vapor pressure of precursor compound)/Pₛᵥ. In an embodiment, the disclosure provides for controlling the temperature of the precursor via controlling the temperature of a carrier gas entering a sublimation vessel, thermally isolating the sublimation vessel, and optionally controlling the temperature upstream and downstream of the precursor bed. These techniques are examples only, and not exhaustive.

In general, the grains in powdered solid precursor materials with high vapor pressures tend to fuse together and turn an originally fluid bed into a solid cake. While the porosity of the material may be maintained, the ability of the material to flow is changed. In a sublimation source where the carrier gas percolates through the precursor bed the rigidity of the precursor bed leads to the problem of cavity formation. A cavity may develop into a channel through the precursor bed. As the controlled sublimation process depends on percolation of the carrier gas through the bed, a channel generally results in decreasing the output vapor concentration to an unpredictable level. The time of such a breakdown is unpredictable. A breakdown normally results in the loss of product made in the CVD process. In addition, there may still be 50% of the original fill of precursor in a prior art bubbler which is lost to waste. The problem of channel formation does not exist in sublimation sources that use advective flow of the carrier gas in close proximity to the precursor bed.

Further, powdered solid materials are poor thermal conductors. The sublimation requires heat. This sublimation heat is currently supplied by uncontrolled heat flows from an environment surrounding the sublimation vessel. The temperature of the precursor material is not controlled and the output concentration of the source not known. In order to enhance heat flow and temperature uniformity, CVD source designs for solid precursors resemble a long and narrow tube on order to dispose the precursor material close to an energy providing surface. This approach works reasonably well to prevent the cavity formation but it is limited in capacity, output, and output stability. Many advection solid sources use baffles to generate one torturous path along the surface of the precursor material to mimic a long channel. For high output it may be advantageous to create a multitude of advective flow paths. The carrier gas flow through the source is split into many smaller flows that combine again at the outlet of the sublimation vessel. The multitude of smaller flows allow a volume of carrier gas to stay for a longer time over the precursor bed to get saturated.

In an embodiment, the apparatuses and methods described herein use the carrier gas for delivering sublimation energy and for obtaining a controlled and stable output vapor concentration. The energy provided by the carrier gas may be evenly applied across the upstream surface of a precursor bed without relying on thermal conduction through walls and the precursor bed. Therefore the bed may be wide and short instead of narrow and long. For example, a single cylinder shaped sublimation vessel with an aspect ratio of length/diameter between 0.5 and 2 (compared to state of the art of 2-10) may be used to hold 3 kilograms or more of a precursor material. This is advantageous for cleaning and filling of the cylinder. It also increases the output (grams per second) of the source.

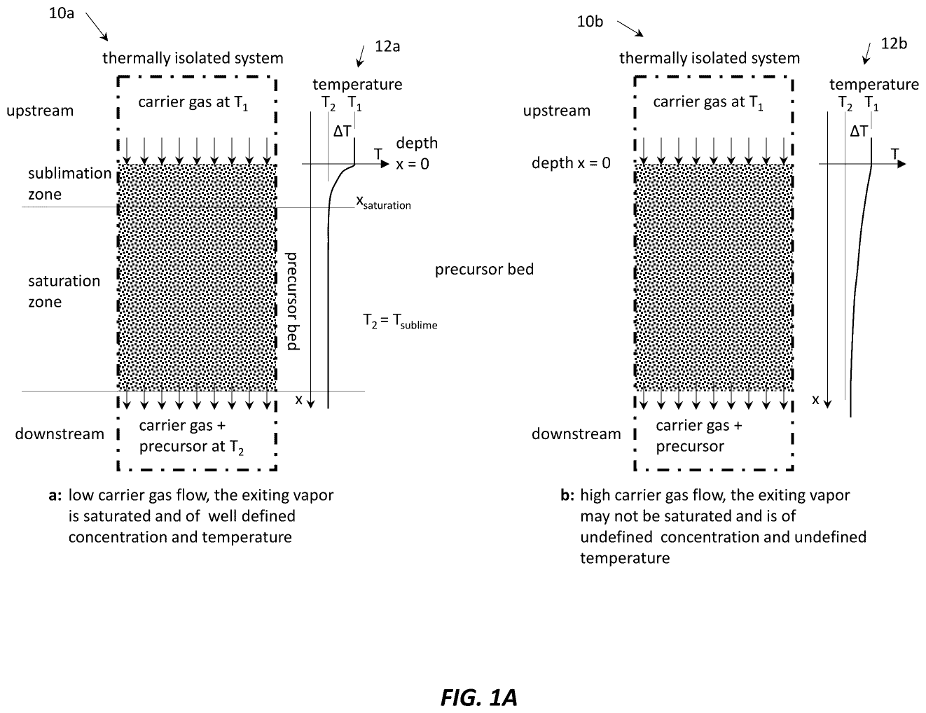

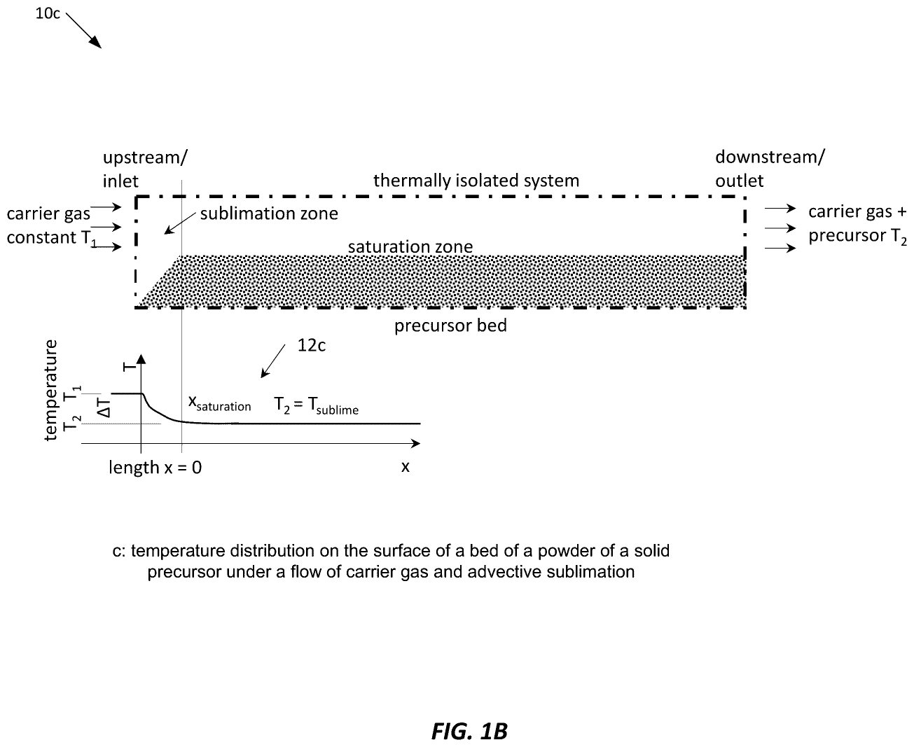

Referring to FIG. 1A, a diagram of two example temperature distributions in a bed of a precursor in a thermally isolated percolation sublimation source at respective low (10a) and high carrier (10b) gas flow F_{cg} are shown. FIG. 1A is an example only and is provided to illustrate the general relationship between a carrier gas flow rate and the precursor temperatures. In a first thermally isolated system 10a, a carrier gas at a first temperature T₁ flows through a precursor bed at a relatively low gas flow rate. All sublimation takes place in the sublimation layer which extends from the upstream surface of the precursor bed to Xₛₐₜᵤᵣₐₜᵢₒₙ. When the saturation of the carrier gas with the precursor vapor is complete the temperature of has fallen to a second temperature T₂. The difference ΔT=T₁−T₂ is a function of the heat spent on the sublimation. As depicted in a first temperature/depth profile curve 12a, at a low carrier gas flow F_{cg}, the carrier gas is saturated with precursor at the depth Xₛₐₜᵤᵣₐₜᵢₒₙ. The exiting vapor is saturated at the second temperature T₂ and of a well defined concentration. In contrast, in an identical second thermally isolated system 10b, the carrier gas at a first temperature T₁ flows through the precursor bed at a relatively higher flow rate. In this second example, as depicted in a second temperature/depth profile curve 12b, the exiting vapor may not be saturated and of an undefined temperature T₂ and concentration.

The temperature profile in the precursor bed along the flow path of the carrier gas depends on a number of factors the largest of which may be the available surface area for the precursor to transition into the gas phase. Coarser pores make Xₛₐₜᵤᵣₐₜᵢₒₙ longer, finer pores make Xₛₐₜᵤᵣₐₜᵢₒₙ shorter.

As discussed above, in prior percolation source designs, cavity and channel formation result from the uneven supply of energy to the precursor bed. While advection sources will not develop channels (advection sources can be thought of as sublimation sources that use a defined channel) the following about heat flows and temperatures applies to both, percolation and advection. At spots where energy is supplied in form of heat, e.g. through a vessel wall, the rate of evaporation is increased relative to the parts of the bed that do not receive heat. That way cavities and channels form near sources of heat. The present disclosure uses the carrier gas as source of energy for the sublimation of a solid precursor. The sidewalls of a sublimation vessel may be thermally isolated to reduce uncontrolled energy (heat) flows. Energy (heat) may be evenly delivered to the upstream surface of the precursor bed by the flowing carrier gas. The temperature of the carrier gas may be controlled based on feedback from the temperatures measured inside the precursor bed using temperature sensors. In an embodiment, a downstream temperature measurement may be used to control the carrier gas temperature at a calculated value. In an independent adjustment the downstream temperature measurement may also be used to control the sublimation vessel pressure and to maintain a constant concentration output.

Referring to FIG. 1B, a diagram of an example temperature distribution in a bed of a precursor in an thermally isolated advection sublimation source 10c with a carrier gas flow F_{cg} is shown. In an example, a precursor material may be spread out over the bottom of a sublimation vessel and the carrier gas flow F_{cg} is directed in close proximity parallel to the precursor surface. In such designs, no percolation occurs. The precursor material diffuses into the carrier gas from the exposed surface. For example, in the thermally isolated system 10c a temperature controlled carrier gas provides heat to the inlet side of the bed. As depicted in a third temperature profile curve 12c similar to 12a, the precursor material sublimes preferentially upstream where it is exposed to the carrier gas. The carrier gas cools as it provides the sublimation energy to the precursor. The length of the precursor bed that is traversed by the carrier gas in an advective sublimation source is analogous to the thickness of the precursor bed in the percolating examples depicted in FIG. 1A.

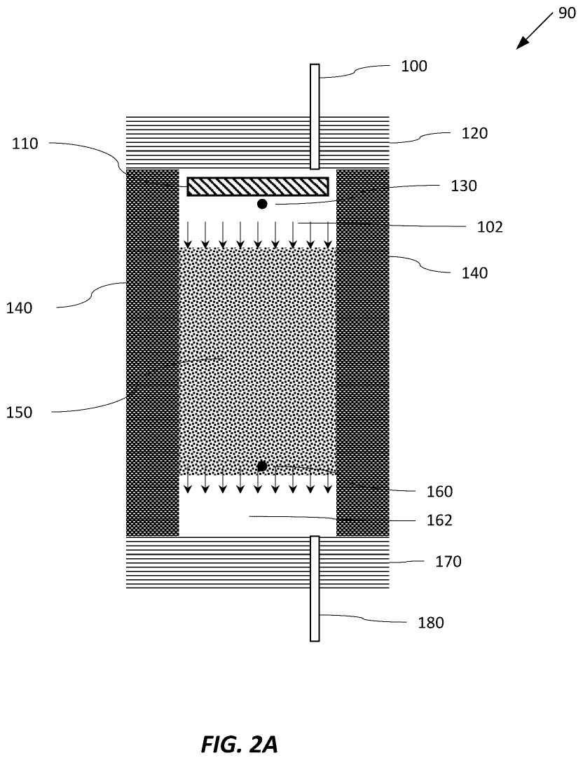

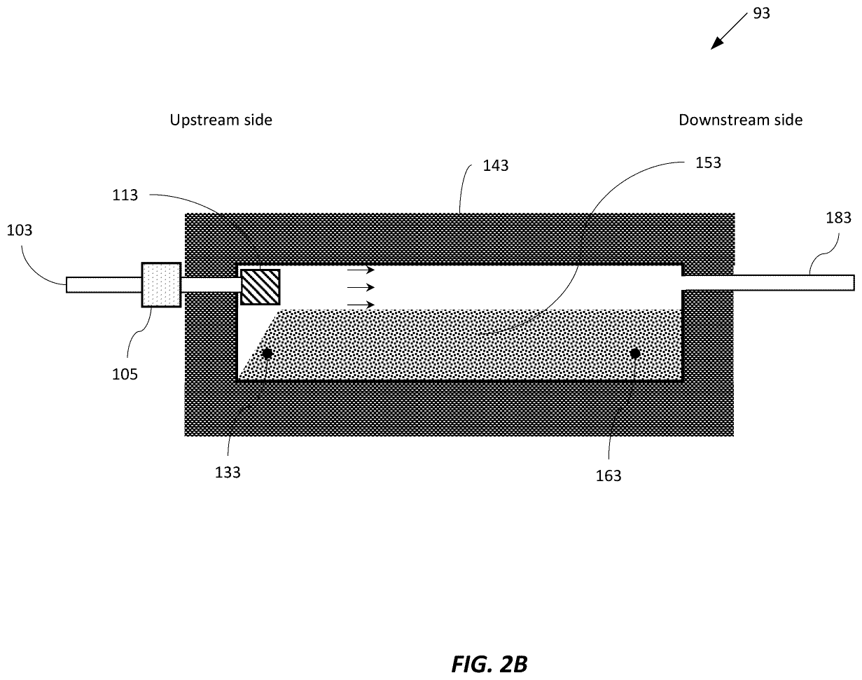

Referring to FIG. 2A, with further reference to FIG. 1A, an example sublimation vessel 90 for the percolation of a carrier gas through the precursor is shown. The sublimation vessel 90 includes a carrier gas inlet port 100, a deflector/turbulator 110, an upstream thermal device 120 (also known as (aka): a top thermal device, inlet thermal device), an upstream temperature sensor 130 (aka: a top temperature sensor, inlet thermal sensor), a thermally insulating exterior wall 140 (aka: a heat insulating enclosure), a precursor bed 150, a downstream temperature sensor 160 (aka: a bottom temperature sensor, outlet temperature sensor), a downstream thermal device 170 (aka: a bottom thermal device, outlet thermal device), and a vapor outlet port 180. In an embodiment, the thermally insulating exterior wall 140 may be a thermally isolating shroud disposed around a sublimation vessel and configured to prevent energy (e.g., heat) from entering the precursor bed 150 from outside sources. In general, the upstream thermal device 120 and the downstream thermal device 170 are located at the respective upstream side of the bed and the downstream side of the bed. The upstream thermal device 120 is configured to allow control of the carrier gas temperature upstream and the downstream thermal device 170 is configured to allow to control the vapor temperature downstream which are measured by the upstream temperature sensor 130 and the downstream temperature sensor 160. As an example, and not a limitation, the sublimation vessel 90 is a cylinder in a vertical orientation. Other forms and orientations may be used. For example, the sublimation vessel 90 may have a cylindrical, square, hexagonal, or any polygonal or irregular cross section, lay on its side or even be inverted. For convenience, in some instances the upstream side of the precursor bed 150 may be referred to as the top, and the downstream side of the precursor bed 150 may be referred to as the bottom.

The sublimation vessel 90 is configured to deliver thermal energy (heat) uniformly to the upstream surface of the precursor bed 150. In general, the configuration recognizes that most of the sublimation energy is obtained from the carrier gas itself. A carrier gas travels from the carrier gas inlet 100, through the upstream thermal device 120 and the deflector/turbulator 110. When the carrier gas enters the precursor bed 150, it picks up the precursor vapor and cools.

Referring to FIG. 2B, with further reference to FIG. 1B, an example sublimation vessel 93 for advective flow of a carrier gas over the precursor is shown. The sublimation vessel 93 includes a carrier gas inlet port 103, a carrier gas heater 105, a deflector/turbulator 113, an upstream temperature sensor 133, a thermally insulating exterior wall 143 (i.e., a heat insulating enclosure), a precursor bed 153, a downstream temperature sensor 163, and a vapor outlet port 183. In an embodiment, the thermally insulating exterior wall 143 may be a thermally isolating shroud disposed around a sublimation vessel and configured to prevent energy (e.g., heat) from entering the precursor bed 153 from outside sources other than the carrier gas heater 105. The carrier gas heater 105 is configured to allow control of the carrier gas temperature and thus the temperature profile 12c in the sublimation vessel 93. As an example, and not a limitation, the sublimation vessel 93 can be configured as a wide cylinder relative to a short height (e.g., disc shaped), such that the precursor bed 153 is disposed in a lower portion of the disc and the carrier gas flowing above the precursor bed 153 in an upper portion of the disc. Other shapes may also be used.

Referring back to FIGS. 1A and 1B, when the carrier gas is saturated at point Xₛₐₜᵤᵣₐₜᵢₒₙ some distance below the surface of the precursor bed 150 or some distance from the carrier gas inlet port 103 across the surface of the precursor bed 153, no more heat is required and the temperature remains constant until the carrier gas plus vapor leaves the sublimation vessel. Example temperature distributions through such precursor beds 150, 153 are shown in the temperature/depth profile curves 12a-c in FIGS. 1A and 1B. A temperature difference ΔT (delta T) develops from the top upstream surface of the precursor bed 150 to the bottom downstream surface of the precursor bed 150, and from the upstream side of the precursor bed 153 to the downstream side of the precursor bed 153. This temperature difference ΔT may be calculated as equation (1) below:

$$Δ T = \frac{VaporPressure ( {T}_{sublime} )}{Sublimation Vessel Pressure} \frac{HeatOfSublimation}{{c}_{p} OfCarrierGas} \qquad ( 1 )$$

As an example for the application of equation (1), trimethylindium (TMIn), a common precursor used in the production of LEDs, may be used. The heat of sublimation of TMIn is 46.7W*minute/standard liter (gas). The specific heat at constant pressure (i.e., “cₚ value”) of nitrogen, a commonly used carrier gas, is 0.0217 W*minute/standard liter/Kelvin. A typical sublimation temperature for TMIn is 17° C. at which the vapor pressure is 0.87 torr. A typical sublimation vessel pressure is 225 torr. The temperature difference to be maintained is:

$$Δ T = \frac{0.87}{225} \frac{46.7}{0.0217} K = 8.43 K .$$

This ΔT value is approximately the same for the use of hydrogen as a carrier gas. Both nitrogen and hydrogen are near ideal gases and their cₚ values per standard liter are similar. In general, equation (1) may be realized when the partial pressure of the carrier gas is at least ten times the vapor pressure of the precursor.

The use of TMIn as precursor is an example only, and not a limitation, as other precursor materials may be used. For example, Table 1 below provides the vapor pressure, temperature, sublimation vessel pressure (Pₛᵥ), the heat of sublimation, and the calculated ΔT for the listed precursors with a nitrogen carrier gas (i.e., cₚ=0.0217 W*minute/standard liter/Kelvin). The ΔT values for other precursor materials not included in Table 1 may also be determined as described above.

TABLE 1

| | | Sub- | | | |
|---|---|---|---|---|---|
| | | limation | | Heat of | |
| | Vapor | Tempera- | | Sub- | |
| Precursor | Pressure | ture | P_{SV} | limation | ΔT |
| trimethylindium | 0.87 torr | 17 C. | 225 torr | 62.7 | 8.43K |
| (TMIn) | | | | kJ/mol | |
| Tetrakis- | 0.1 torr | 49 C. | 50 torr | 57.3 | 3.94K |
| dimethylamino | | | | kJ/mol | |
| Zirconium | | | | | |
| (TDMAZr) | | | | | |
| Pentakis | 2.1 ton | 100 C. | 200 torr | 89.0 | 32.9K |
| (dimethylamino) | | | | kJ/mol | |
| Tantalum | | | | | |
| PDMATa | | | | | |

The sublimation vessels 90, 93 utilize the carrier gas for the delivery of the sublimation energy. The deflectors/turbulators 110, 113 assist in evenly distributing the carrier gas temperature over the upstream surface of the bed, which enables the precursor beds 150, 153 to be wide and short.

Again referring to FIG. 2A, the art is still using narrow and long sublimation vessels for percolation sublimation. Long and narrow sublimation vessels are expensive to operate and limited in capacity which makes them less desirable for large scale use. In an example, deflector/turbulator 110 may be configured to shape a flow of the carrier gas in the sublimation vessel to create a uniform flow velocity of the carrier gas normal to an upstream surface of the solid precursor material in the precursor bed 150. When the temperature of the carrier gas above the precursor bed 150 is uniform, and the thermally insulating exterior walls 140 prevent heat from entering, sublimation takes place uniformly in a thin layer beneath the surface of the precursor bed 150. As a result, a single cylinder with an aspect ratio of length/diameter of less than 1 may be sized to hold a substantial amount of precursor. The low aspect ratio is also advantageous for cleaning and filling of the cylinder. It also increases the output of the source because the top surface of the bed is large which means that the carrier gas flow through a unit of the surface area is low and the temperature gradient under the surface steep and thus Xₛₐₜᵤᵣₐₜᵢₒₙ is close to the surface. As illustrated in FIG. 1A, steep temperature gradients below the upstream surface may be desirable for full utilization.

Again referring to FIG. 2B in an example, deflector/turbulator 113 may be configured to shape a flow of the carrier gas in the sublimation vessel to flow across a surface of the solid precursor material in the precursor bed 153. The temperature of the carrier gas becomes lower when it provides the heat of sublimation to the precursor bed 153 as the thermally insulating exterior walls 143 prevent heat from entering. The sublimation takes place in the sublimation zone that stretches over a distance from the upstream edge of the precursor bed 153 to the location where the carrier gas is saturated with the vapor. As illustrated in FIG. 1B, steep temperature gradients in the sublimation zone may be desirable for full utilization. The upstream edge of the precursor bed is consumed by sublimation. No precursor material is picked up in the saturation zone. In use the upstream edge of the precursor bed 153 takes the shape of a wedge. The angle of the wedge depends primarily on the flow velocity of the carrier gas and the vapor pressure of the precursor material. During use the upstream edge of the precursor bed 153 travels toward the outlet port.

The ΔT for TMIn is 3° C. to 10° C. under common operating conditions and source output. Such a temperature difference can be managed using a thermal device that comprises a resistive heater and a thermoelectric cooler. As indicated in Equation (1), ΔT does not depend on the carrier gas flow. The mass of sublimated precursor per time increases linearly with the carrier gas flow, and the energy supply also increases linearly with the carrier gas flow. Therefore, as more carrier gas flows into the respective sublimation vessels 90, 93 more energy is supplied by the carrier gas, and more precursor is sublimated.

An output concentration c may be expressed as

$$c = \frac{VaporPressure ( {T}_{sublime} )}{Sublimation Vessel Pressure} \qquad ( 2 )$$

where, T_{sublime} is the temperature at the downstream side (e.g., bottom) of the precursor bed 150.

In operation, in a first example, FIG. 2A the carrier gas enters the sublimation vessel 90 via the carrier gas inlet port 100. The upstream thermal device 120 is configured to heat the carrier gas prior to entering the sublimation vessel 90 as well as heat the carrier gas in the top portion of the sublimation vessel 90. The deflector/turbulator 110 is configured to deflect/diffuse the incoming carrier gas over the top of the precursor bed 150. For example, the deflector/turbulator 110 is a mean for shaping a flow of the temperature-controlled carrier gas in the sublimation vessel to create a uniform flow velocity of the carrier gas normal to an upstream surface of the solid precursor material. The upstream temperature sensor 130 is configured to sense the temperature in the upstream area or space around the precursor bed 150. The terms area and space will be used interchangeably to describe a three dimensional volume. The temperature of the upstream thermal device 120 may be controlled, at least in part, based on the temperature sensed by the upstream temperature sensor 130 and the downstream temperature sensor 160. The carrier gas flows through the precursor bed 150 picking up the sublimating precursor material, and then out through the vapor output port 180, generally to a deposition chamber (not shown) in fluid communication with vapor output port 180. The downstream temperature sensor 160 is configured to detect the temperature in the downstream space around the vapor output port 180 (i.e., the temperature of the carrier gas and the entrained vapor exiting the sublimation vessel). The downstream thermal device 170 is configured to provide heat to the sublimation vessel 90 and may be controlled, at least in part, based on the temperature sensed by the upstream temperature sensor 130 and the downstream temperature sensor 160. The thermal devices 120, 170 are typically electric heaters configured to receive an electric input and vary a heat output based on control signals. Other controllable heat sources (e.g. thermoelectric coolers) may also be used.

In operation, in a second example, FIG. 2B the carrier gas enters the sublimation vessel 93 via the carrier gas inlet port 103. The carrier gas heater 105 is configured to heat the carrier gas prior to entering the sublimation vessel 93 and the deflector/turbulator 113 is configured to deflect/diffuse the incoming carrier gas over the top of the precursor bed 153. For example, the deflector/turbulator 113 is a mean for shaping a flow of the temperature-controlled carrier gas in the sublimation vessel to create a predetermined flow velocity of the carrier gas above the surface of the solid precursor bed 153. The upstream temperature sensor 133 is configured detect the temperature on the upstream side or space around the precursor bed 153. The carrier gas heater 105 may be controlled, at least in part, based on the temperature sensed by the upstream temperature sensor 133 and the downstream temperature sensor 163. The carrier gas flows over the precursor bed 153, picks up the sublimating precursor material, and then flows out through the vapor output port 183. The downstream temperature sensor 163 is configured to detect the temperature in the downstream space around the vapor output port 183 (i.e., the temperature of the carrier gas and the entrained vapor exiting the sublimation vessel). The carrier gas heater 105 may be an electric heater configured to receive an electric input and vary a heat of the carrier gas output based on control signals. Other controllable heat sources (e.g. thermoelectric coolers) may also be used.

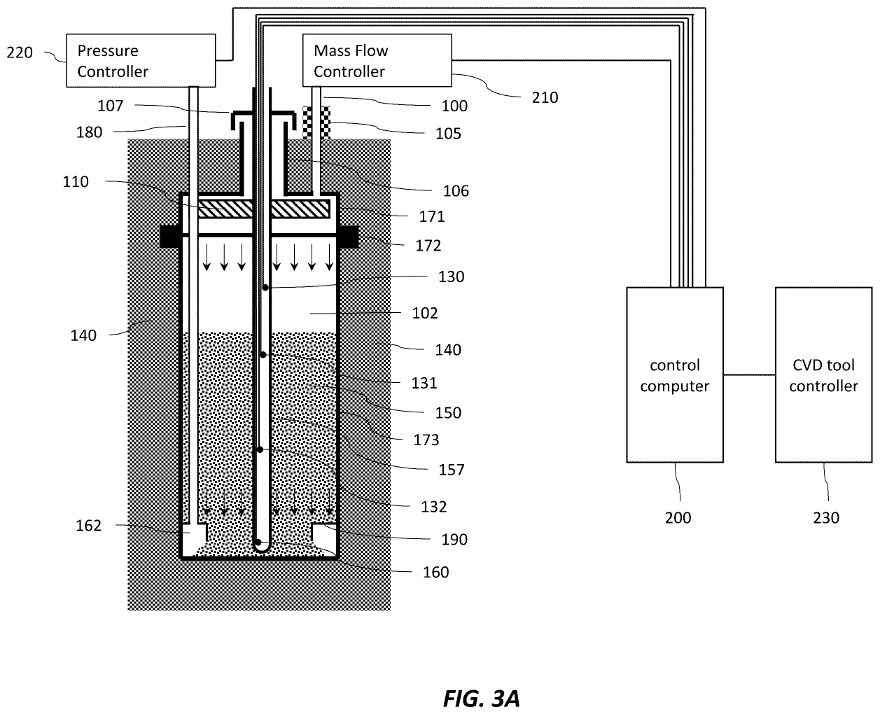

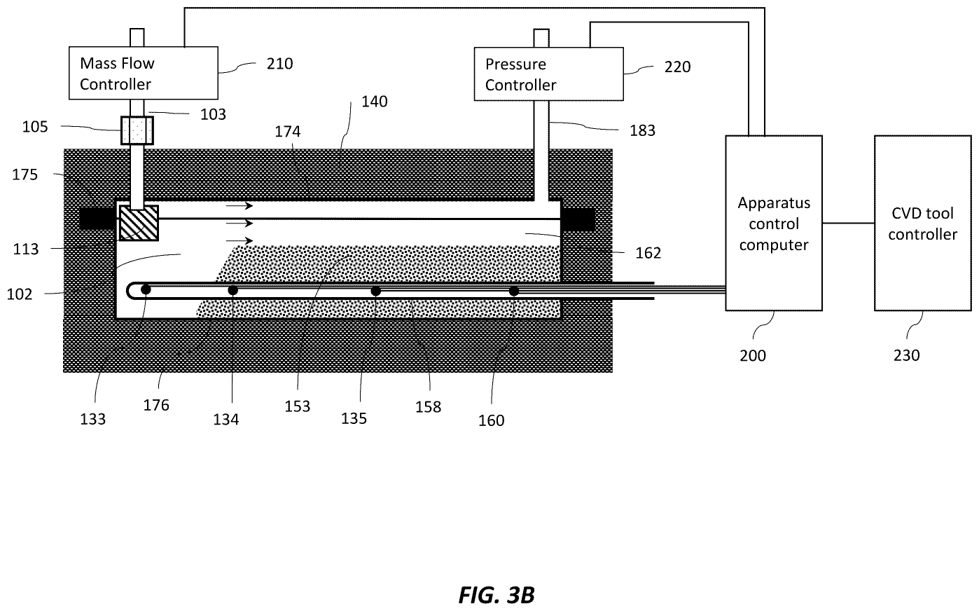

Referring to FIG. 3, with further reference to FIGS. 1 and 2, two examples of solid precursor vapor sources are shown. Both examples of a solid precursor vapor source include a sublimation vessel and attachments configured for the purpose of uniformly subliming the solid precursor. The elements of both examples of the solid precursor vapor source and the attachments are the same. They are arranged differently in the first example FIG. 3A and the second example FIG. 3B. In both examples the sublimation vessel comprises a lid 171, 174 and a pan 173, 176 which are joined by the flange 172, 175. The attachments to both sublimation vessels include a thermal insulation for the exterior walls 140, 143, and a carrier gas thermal device (heater) 105. which is operably coupled to and controlled by an apparatus control computer 200.

Referring to FIG. 3A, with further reference to FIGS. 1A and 2A, a first example solid precursor vapor source is shown. The vertical flow percolation solid precursor vapor source includes a sublimation vessel comprising lid 171, the pan 173 and flange 172 and attachments configured for the purpose of uniformly subliming the solid precursor. The sublimation vessel may be a cylindrical container with a preferably flat top and bottom. The lid 171 of the sublimation vessel may include a number of ports: at least, a carrier gas inlet port 100, a vapor outlet port 180, and a sensor port 106 configured to allow access to the sublimation vessel for temperature sensing. As an example, the sensor port 106 may have an open diameter of 10-20 mm and may be capped with a cap 107. In an example, the cap 107 of the sensor port 106 may be fitted with at least one sensing tube 157 that penetrates into the pan 173, which may be called sublimation vessel pot, and the precursor bed 150 and houses two or more temperature sensors such as the upstream temperature sensor 130 and the downstream temperature sensor 160. More temperature sensors 131, 132 may be disposed between temperature sensors 130 and 160. Temperature sensors 131 and 132 are useful to measure local temperatures in the precursor bed 150. Other means may also be used to dispose the downstream temperature sensor 160 and the upstream temperature sensor 130 within the sublimation vessel.

Referring to FIG. 3B, with further reference to FIGS. 1B and 2B, a second example solid precursor vapor source is shown. The horizontal flow advection precursor vapor source includes the sublimation vessel comprising a lid 174, a pan 176 and a flange 175, the thermal insulation for the exterior walls 143, and the carrier gas heater 105 (e.g., inlet heater). The lid 174 of the sublimation vessel includes the carrier gas inlet port 103 and the vapor outlet port 183. The pan 176 includes at least one sensing tube 158 that penetrates into the precursor bed 153 and house at least the upstream temperature sensor 133 and the downstream temperature sensor 163. The deflector or turbulator 113 transforms the jet of carrier gas emanating from the carrier gas inlet 103 into turbulent flow. The carrier gas goes through the carrier gas heater 105 before entering the sublimation vessel where it is heated to T_{downstream}+ΔT and measured by the upstream temperature sensor 133. The apparatus control computer 200 may be operably coupled to the carrier gas heater 105, the upstream temperature sensor 130 and the downstream temperature sensor 160 and configured to control the temperatures within the sublimation vessel. More temperature sensors 134, 135 may be disposed between temperature sensors 130 and 160. Temperature sensors 134 and 135 are useful to measure local temperatures in the precursor bed 150. Other means may also be used to dispose the downstream temperature sensor 160 and the upstream temperature sensor 130 within the sublimation vessel.

In both examples (FIG. 3A and FIG. 3B) the apparatus control computer 200 may be operably coupled to and configured to adjust the mass flow controller (MFC) 210 or the pressure controller 220. The apparatus control computer 200 is configured to calculate a compensated pressure value P_{SVC} or carrier gas flow value F_{CGC} from the difference between nominal temperature Tₙₒₘᵢₙₐₗ (i.e., the temperature that the user has used for their recipe for the CVD process) and the temperature measured by the downstream temperature sensors 160, 163, T _{downstream}. The flow is compensation factor is:

$${f}_{flow} = \frac{vapor pressure ( {T}_{nominal} )}{vapor pressure ( {T}_{downstream} )} \qquad ( 3 )$$

and the pressure compensation factor is:

$${f}_{pressure} = \frac{vapor pressure ( {T}_{downstream} )}{vapor pressure ( {T}_{nominal} )} \qquad ( 4 )$$

The application of the compensation factor f_{flow} to the recipe carrier gas flow maintains the same output mass flow rate of the precursor as would occur when the precursor is at recipe temperature T_{sublime} and the carrier gas at the recipe flow. The application of the compensation factor fₚᵣₑₛₛᵤᵣₑ to the recipe sublimation vessel pressure maintains the same output concentration

Further, the apparatus control computer 200 may be operably coupled to a tool controller, such as a CVD tool controller 230 and configured to exchange process control data such as precursor information, carrier gas information, chamber pressure and carrier gas flow rates. In the example FIG. 3, the apparatus control computer 200 may be programmed with the vapor pressure curve and the heat of sublimation of the precursor. The apparatus control computer 200 may also programmed with sublimation vessel pressure (P_{SV}) value for the recipe P_{SVR} and the sublimation temperature value for the recipe Tₙₒₘᵢₙₐₗ or alternatively with the desired output concentration c. The data within apparatus control computer 200 may be input by the user or provided by the CVD tool controller 230. The apparatus control computer 200 may utilize the data to calculate the ΔT that is required to provide the required sublimation energy. The controller is configured to drive the carrier gas heater to maintain Tᵤₚₛₜᵣₑₐₘ and T_{downstream}. T_{downstream} may be measured near outlet area 162 (e.g. the area proximate to the downstream temperature sensor 160, 163) and T_{downstream}+ΔT may be measured in the inlet area 102 (e.g., the area proximate to the upstream temperature sensors 130, 133). The thermally insulating exterior walls 140, 143 are configured to reduce or preferably prevent outside energy from entering the precursor bed 150, 153 by pathways other than the carrier gas. When the heated carrier gas enters the sublimation vessel through the carrier gas inlet 100, 103 it is broken into turbulent flow by the deflector/turbulator 110, 113. After the carrier gas has passed through or traversed the precursor bed 150, 153 and is saturated with the precursor, it d exits the sublimation vessel via the vapor outlet port 180, 183.

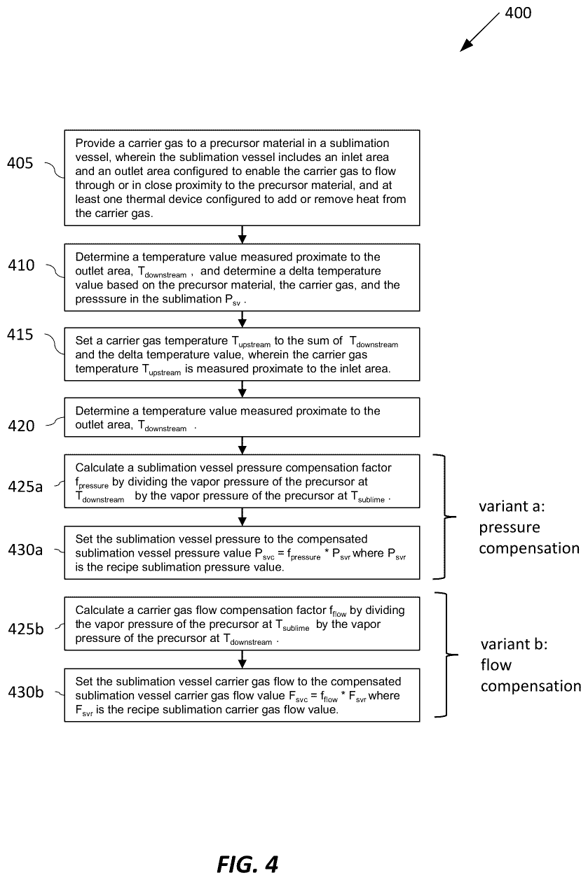

Referring to FIG. 4, with further reference to FIGS. 1-3, a method 400 for controlling a solid precursor vapor source includes the stages shown. The method 400 is, however, an example only and not limiting. The method 400 may be altered, e.g., by having stages added, removed, rearranged, combined, performed concurrently, and/or having single stages split into multiple stages. For example, stage 410 described below for determining a sublimation temperature value and a delta temperature value may be performed before stage 405. Still other alterations to the method 400 as shown and described are possible.

At stage 405, the method 400 includes providing a carrier gas to a precursor material in a sublimation vessel, wherein the sublimation vessel includes an inlet area 102 and an outlet area 162 configured to enable the carrier gas to flow through or near the precursor material, and at least one thermal device configured to add or remove heat from the sublimation vessel. In an example, the carrier gas inlet port 100, 103 may be a means for providing the carrier gas to the precursor bed 150, 153. The carrier gas may be, for example, nitrogen, hydrogen, or other gases used in chemical vapor deposition processes. The mass flow controller 210 may be used to regulate the flow of the carrier gas into the sublimation vessel. One or more deflectors or turbulators 110, 113 may be used to diffuse the carrier gas over the precursor bed 150, 153. The inlet area 102 of the sublimation vessel may be defined as the area or volume of space within the sublimation vessel proximate to the precursor bed 150, 153 and the upstream temperature sensors 130, 133. The outlet area 162 of the sublimation vessel may be defined as the area or volume of space within the sublimation vessel proximate to, or within, the downstream side of the precursor bed 150, 153 and the downstream temperature sensor 160, 163. The at least one thermal device may be the upstream thermal device 120, the downstream thermal device 170, the carrier gas heater 105 or other thermal devices configured to heat the carrier gas entering the sublimation vessel. At stage 405, the method 400 may include confining the carrier gas flow to an open space above the surface of the precursor bed extending at least 1 mm but not more than 100 mm above the surface of the precursor bed, and preferably 5 mm to 15 mm.

At stage 410, the method 400 includes determining a downstream temperature value T_{downstream} and a delta temperature value (ΔT) based on the precursor material and the carrier gas. The delta temperature value may be calculated based on equation (1) above by the apparatus control computer 200. In an example, the apparatus control computer 200 may include a data structure (e.g., data base, flat file, look-up table) configured to store the sublimation temperature value and delta temperature value and the associated precursor material and the carrier gas information (e.g., the cₚ value). In an example, a user may enter the sublimation temperature value and delta temperature value directly into the apparatus control computer 200. The sublimation temperature value may be provided to the apparatus control computer 200 by other sources (e.g., local or networked) such as the CVD tool controller 230, or other manufacturing systems. The sublimation temperature value and the delta temperature value may vary based on the CVD application and the associated precursor material, carrier gas, and the sublimation vessel pressure for the CVD application.

At stage 415, the method 400 includes setting the upstream temperature Tᵤₚₛₜᵣₑₐₘ in the sublimation vessel based on the downstream temperature T_{downstream} value and the delta temperature value, wherein Tᵤₚₛₜᵣₑₐₘ is measured proximate to the inlet area 102. The carrier gas heater 105 and the upstream temperature sensor 130 may be a means for controlling the upstream temperature. In an example, the carrier gas may be heated or cooled as it flows through the carrier gas heater 105. The carrier gas heater 105 may be a component in a closed-loop control system (e.g., PID) with the upstream temperature sensor 130 and the apparatus control computer 200. Other control solutions may also be used. The temperature proximate to the inlet area 102 is controlled to be approximately the sum of the downstream temperature value and the delta temperature value (i.e., T_{downstream}+ΔT). For example, a typical sublimation temperature value for TMIn is 17 degrees Celsius at which the vapor pressure is 0.87 torr. The delta temperature value (ΔT) for TMIn as described above is 3 to 10 degrees Celsius depending on the sublimation vessel pressure as controlled by pressure controller 220. In this example, the upstream temperature in the sublimation vessel may be set to a value within a range of 20-30 degrees Celsius. The carrier gas heater may be a resistive heater and a thermoelectric cooler configured to maintain the temperature in the inlet area 102 in this range.

At stage 420, the method 400 includes determining the downstream temperature T_{downstream} using the downstream temperature sensor 160,163.

At stage 425 (either stage 425a or 425b), the method 400 includes calculating a compensation factor by comparing the vapor pressure of the precursor at the nominal sublimation temperature and the vapor pressure at the measured downstream temperature. There are two variants to achieve an acceptable compensation of the outlet concentration for the temperature error between the recipe temperature T_{sublime} and the measured temperature T_{downstream}. Variant a), in stage 425a calculates a compensation factor for the sublimation vessel pressure, variant b), stage 425b calculates the compensation factor for the carrier gas flow.

At stage 430 (either stage 430a or 430b), the method 400 includes setting the compensated values that were calculated in stage 425. At stage 430a the method 400 includes setting the sublimation vessel pressure Pₛᵥ to the compensated sublimation vessel pressure value P_{svc}. At stage 430b the method 400 includes setting the carrier gas flow F_{CG}through the sublimation source to the compensated carrier gas flow value F_{CGC}.

The method 400 may return to stage 410.

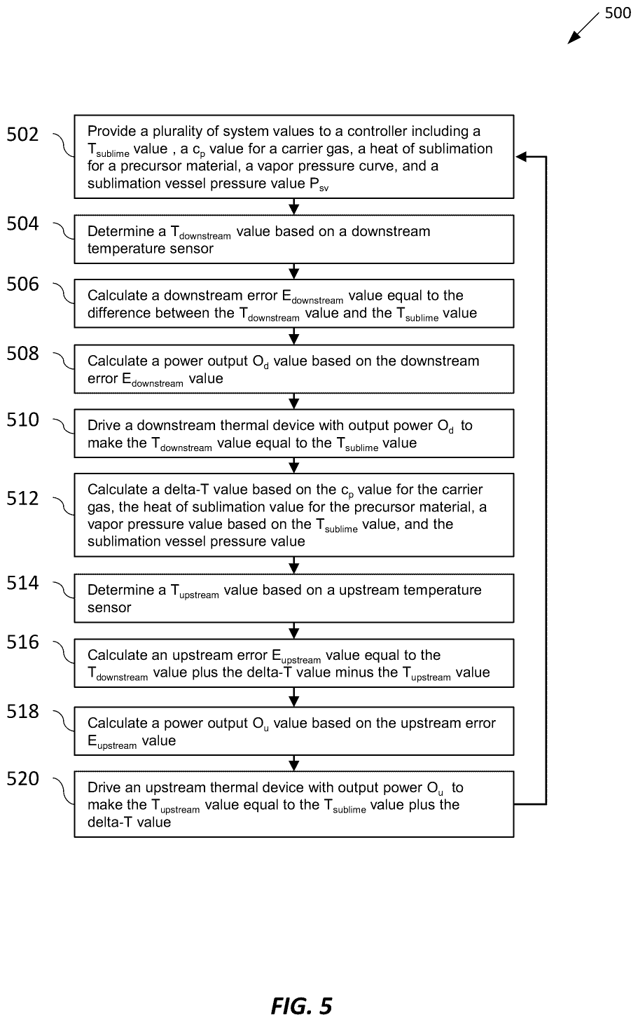

Referring to FIG. 5, with further reference to FIGS. 1-3, a process 500 for controlling downstream and upstream thermal devices in a solid precursor vapor source includes the stages shown. The process 500 is, however, an example only and not limiting. The process 500 may be altered, e.g., by having stages added, removed, rearranged, combined, performed concurrently, and/or having single stages split into multiple stages. The apparatus control computer 200 may be a means for executing the process 500.

At stage 502, the process 500 includes providing a plurality of system values to a controller including a T_{sublime} value, a cₚ value for a carrier gas, a heat of sublimation for a precursor material, a vapor pressure curve, and a sublimation vessel pressure value Pₛᵥ. The apparatus control computer 200 may be a means for providing the plurality of system values. For example, the apparatus control computer 200 may include a memory with one or more data structures containing the system values. Such a data structure may obtain data from other electronic sources (e.g., local or networked), or may receive them via a user interface (e.g., user data entry). In an example, one or more of the system values may be obtained via another system such as the CVD tool controller 230. The vapor pressure curve may be an array of values in a data structure corresponding to vapor pressure values as a function of temperature for different precursor materials. The cₚ value for the carrier gas is the specific heat at constant pressure for the carrier gas (e.g., 0.0217 W*min/standard liter/Kelvin for nitrogen). The sublimation vessel pressure (Pₛᵥ) value is the pressure within the sublimation vessel and more specifically the pressure near the outlet area 162. The T_{sublime} may be a nominal temperature Tₙₒₘᵢₙₐₗ that a CVD process recipe uses for the precursor temperature. That is, because sublimation cools the precursor, the temperature of the precursor will locally be less than T_{sublime} when the process is running. The process 500 determines the difference between T_{sublime} and T_{downstream} and Tᵤₚₛₜᵣₑₐₘ and makes adjustments to temperatures, carrier gas flow or sublimation vessel pressure to keep the outlet mass flow of the precursor constant. The heat of sublimation for a precursor material is a material constant of the precursor. The heat of sublimation represents the energy to be supplied in order to sublime one unit mass of precursor. As described herein, for many precursors, the sublimation energy may be supplied through heat from the carrier gas.

At stage 504, the process 500 includes determining a T_{downstream} value based on a downstream temperature sensor. The apparatus control computer 200 may be a means for determining the T_{downstream} value. The downstream temperature sensor 160 is operably coupled to the apparatus control computer 200 and is configured to provide a temperature reading in the area proximate to the bottom of the precursor bed 150 near the outlet area 162.

At stage 506, the process 500 includes calculating a downstream error E_{downstream} value equal to the difference between the T_{downstream} value and the T_{sublime} value. The apparatus control computer 200 may be a means for determining the downstream error E_{downstream} value. The downstream error E_{downstream} value is the difference between the temperature measured by the downstream temperature sensor 160 and the T_{sublime} value provided at stage 502.

At stage 508, the process 500 includes calculating an control output O_{d} value based on the downstream error E_{downstream} value. The apparatus control computer 200 may be a means for calculating the power output O_{d} value. The power output O_{d} value may be a digital or analog control signal based on the size of the downstream error E_{downstream} value, and configured to adjust the operation of the downstream thermal device 170.

At stage 510, the process 500 includes controlling a downstream thermal device based on the power output O_{downstream} value to make the T_{downstream} value equal the T_{sublime} value. The apparatus control computer 200 may be a means of controlling the downstream thermal device 170. (e.g., increase or decrease the temperature) The apparatus control computer 200 is configured to change the temperature of the downstream thermal device 170 as to drive the downstream temperature error E_{downstream} to a minimum. (i.e. the downstream temperature T_{downstream} value to be equal to the T_{sublime} value).

At stage 512, the process 500 includes calculating a delta-T value (ΔT) based on the cₚ value for the carrier gas, the heat of sublimation value for the precursor material, a vapor pressure value based on the T_{sublime} value, and the sublimation vessel pressure (Pₛᵥ) value. The apparatus control computer 200 may be a means for calculating the delta-T value. For example, the delta-T value may be calculated based on equation (1) (e.g., (the vapor pressure based on the T_{sublime} value/the sublimation vessel pressure value)*(heat of sublimation value for the precursor material/the cₚ value for the carrier gas).

At stage 514, the process 500 includes determining a Tᵤₚₛₜᵣₑₐₘ value based on a upstream temperature sensor. The apparatus control computer 200 may be a means for determining the Tᵤₚₛₜᵣₑₐₘ value. The upstream temperature sensor 130 is operably coupled to the apparatus control computer 200 and configured to sense the temperature in the inlet area 102 near the precursor bed 150.

At stage 516, the process 500 includes calculating an upstream error Eᵤₚₛₜᵣₑₐₘ value equal to the T_{downstream} value plus the delta-T value minus the Tᵤₚₛₜᵣₑₐₘ value. The apparatus control computer 200 may be a means for determining the upstream temperature error Eᵤₚₛₜᵣₑₐₘ value. The upstream error Eᵤₚₛₜᵣₑₐₘ value is the difference between the temperature measured by the upstream temperature sensor 130 and the total of the T_{downstream} value provided at stage 504 and the delta-T value calculated at stage 512 (i.e., Eᵤₚₛₜᵣₑₐₘ=(T_{sublime}+ΔT)−Tᵤₚₛₜᵣₑₐₘ).

At stage 518, the process 500 includes calculating a power output Oᵤ value based on the upstream temperature error Eᵤₚₛₜᵣₑₐₘ value (i.e. the difference between the current Tᵤₚₛₜᵣₑₐₘ value and the total of the current T_{downstream} value and the computed delta-T value (T_{downstream}+ΔT)). The apparatus control computer 200 may be a means for calculating the power output Oᵤ value. The power output Oᵤ value may be a digital or analog control signal based on the size of the upstream error Eᵤₚₛₜᵣₑₐₘ value, and configured to adjust the operation of the carrier gas heater device 105.

At stage 520, the process 500 includes controlling a carrier gas heater based on the output Oᵤ value to make the Tᵤₚₛₜᵣₑₐₘ value equal to the T_{downstream} value plus the delta-T value. The apparatus control computer 200 may be a means of controlling the carrier gas heater 105 . . . (e.g., increase or decrease the temperature output) as to drive the upstream error Eᵤₚₛₜᵣₑₐₘ to the minimum The apparatus control computer 200 is configured to change the temperature of the carrier gas heater 105 to make the temperature in the area of the upstream temperature sensor 130 to be equal to the total of the current T_{downstream} value and the computed delta-T value (i.e., T_{sublime}+ΔT).

The process 500 may return to stage 504 to continue to control the carrier gas heater 105 and the downstream thermal device 170.

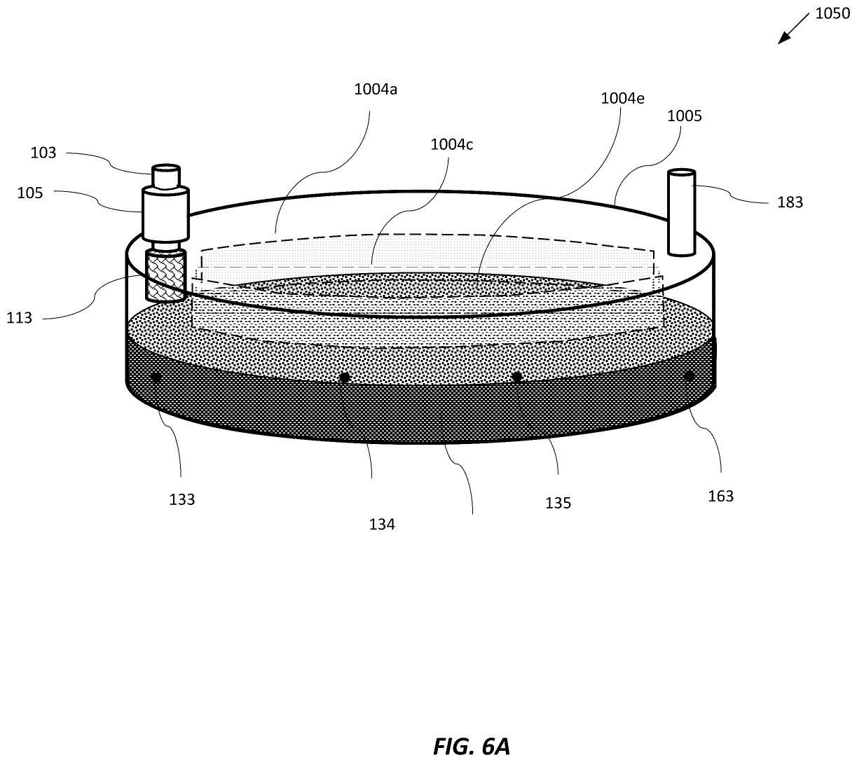

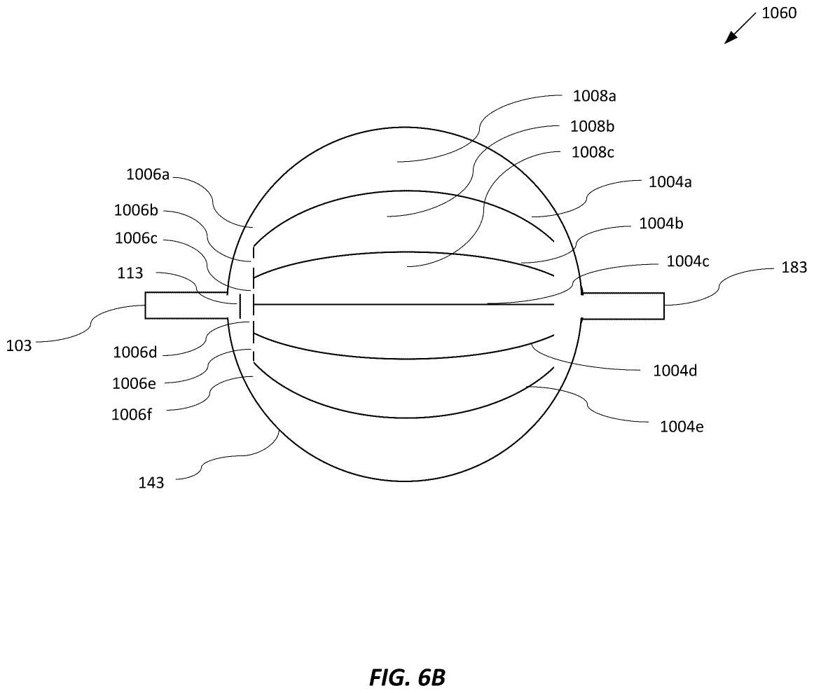

Referring to FIG. 6A, a perspective diagram of an example advective flow precursor vapor source 1050 is shown. The example precursor vapor source 1050 can be disc shaped and is an embodiment of the precursor vapor sources described in FIG. 3B with the addition of baffles 1004. The carrier gas can be heated by the carrier gas heater 105 and flows into the sublimation vessel 1005 through the carrier gas inlet 103 and through the deflector/turbulator 113 and over the surface of the precursor bed 153. Baffles 1004a, 1004b, and 1004c are configured to spread out the flow of the carrier gas over the entire surface of the precursor bed 153 in a predefined way. The baffles 1004a, 1004b, and 1004c create a number of flow paths inside precursor vapor source 1050. The carrier gas flows toward the vapor output 183 through these flow paths as described in FIG. 6B below.

Referring to FIG. 6B, a diagram of an example precursor vapor source 1060 using a set of baffles 1004 to direct a carrier gas to flow over a solid precursor bed is shown. Each flow path that is established by the baffles 1004 has a flow restrictor 1006 on its inlet. The flow restrictor apportions the carrier gas flow F_{cg} according to the length of the flow path that it feeds. In order to traverse the precursor bed 153 in the same amount of time, a longer flow path requires a higher flow (velocity) than a shorter path. Considering FIG. 6B we use the following table as an example for a flow distribution in a circular sublimation vessel with the crescent shaped baffles arranged as shown. Because of the symmetry of the baffle pattern, one-half of the sublimation vessel may be examined. To illustrate the function of baffles 1004a, 1004b, 1004c, 1004d, 1004e and flow restrictors 1006a, 1006b through 1006f, TABLE 2 shows an example of the fraction of the carrier gas flow that follows a particular flow path. TABLE 2 is an example only and not to scale with FIG. 6A or FIG. 6B.

TABLE 2

| | | Share of Total | |
|---|---|---|---|
| Flow Path | Relative Length | Length | Share of Flow |
| 1008a | 1.4 | 39% | F_{cg} * 0.39 |
| 1008b | 1.2 | 33% | F_{cg} * 0.33 |
| 1008c | 1.0 | 29% | F_{cg} * 0.29 |

Those skilled in the art can readily design flow restrictors that provide the desired flow in the flow paths. As an example, the flow restrictor 1006a feeding flow path 1008a may have 39 standard openings (e.g. holes of a suitable diameter), the flow resistor 1006b feeding flow path 1008b may have 33 standard openings, and the flow restrictor 1006c feeding flow path 1008c may have 29 standard openings. A standard opening could have any shape but may preferably be a hole of preferably 0.5 mm diameter or any diameter between 0.1 mm or 2.0 mm.

Sublimation vessel 1005 may have a square shape instead of a circular shape. For a square sublimation vessel with parallel baffles the flow paths are of equal length and the carrier gas flow F_{cg} is equally divided between the channels.

Other examples and implementations are within the scope of the disclosure and appended claims. For example, due to the nature of software and computers, functions described above can be implemented using software executed by a processor, hardware, firmware, hardwiring, or a combination of any of these. Features implementing functions may also be physically located at various positions, including being distributed such that portions of functions are implemented at different physical locations.

As used herein, the singular forms “a,” “an,” and “the” include the plural forms as well, unless the context clearly indicates otherwise.

The terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

Also, as used herein, a list of items prefaced by “at least one of” or prefaced by “one or more of” indicates a disjunctive list such that, for example, a list of “at least one of A, B, or C,” or a list of “at least one of A, B, and C,” or a list of “one or more of A, B, or C”, or a list of “one or more of A, B, and C,” or a list of “A or B or C” means A, or B, or C, or AB (A and B), or AC (A and C), or BC (B and C), or ABC (i.e., A and B and C), or combinations with more than one feature (e.g., AA, AAB, ABBC, etc.). Thus, a recitation that an item, e.g., a processor, is configured to perform a function regarding at least one of A or B, or a recitation that an item is configured to perform a function A or a function B, means that the item may be configured to perform the function regarding A, or may be configured to perform the function regarding B, or may be configured to perform the function regarding A and B. For example, a phrase of “a processor configured to measure at least one of A or B” or “a processor configured to measure A or measure B” means that the processor may be configured to measure A (and may or may not be configured to measure B), or may be configured to measure B (and may or may not be configured to measure A), or may be configured to measure A and measure B (and may be configured to select which, or both, of A and B to measure). Similarly, a recitation of a means for measuring at least one of A or B includes means for measuring A (which may or may not be able to measure B), or means for measuring B (and may or may not be configured to measure A), or means for measuring A and B (which may be able to select which, or both, of A and B to measure). As another example, a recitation that an item, e.g., a processor, is configured to at least one of perform function X or perform function Y means that the item may be configured to perform the function X, or may be configured to perform the function Y, or may be configured to perform the function X and to perform the function Y. For example, a phrase of “a processor configured to at least one of measure X or measure Y” means that the processor may be configured to measure X (and may or may not be configured to measure Y), or may be configured to measure Y (and may or may not be configured to measure X), or may be configured to measure X and to measure Y (and may be configured to select which, or both, of X and Y to measure).

As used herein, unless otherwise stated, a statement that a function or operation is “based on” an item or condition means that the function or operation is based on the stated item or condition and may be based on one or more items and/or conditions in addition to the stated item or condition.

Substantial variations may be made in accordance with specific requirements. For example, customized hardware might also be used, and/or particular elements might be implemented in hardware, software (including portable software, such as applets, etc.) executed by a processor, or both. Further, connection to other computing devices such as network input/output devices may be employed. Components, functional or otherwise, shown in the figures and/or discussed herein as being connected or communicating with each other are communicatively coupled unless otherwise noted. That is, they may be directly or indirectly connected to enable communication between them.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description herein to provide a thorough understanding of example configurations (including implementations). However, configurations may be practiced without these specific details. For example, well-known circuits, processes, algorithms, structures, and techniques have been shown without unnecessary detail in order to avoid obscuring the configurations. The description herein provides example configurations, and does not limit the scope, applicability, or configurations of the claims. Rather, the preceding description of the configurations provides a description for implementing described techniques. Various changes may be made in the function and arrangement of elements.

Also, configurations may be described as a process which is depicted as a flow diagram or block diagram. Although each may describe the operations as a sequential process, some operations may be performed in parallel or concurrently. In addition, the order of the operations may be rearranged. A process may have additional stages or functions not included in the figure. Furthermore, examples of the methods may be implemented by hardware, software, firmware, middleware, microcode, hardware description languages, or any combination thereof. When implemented in software, firmware, middleware, or microcode, the program code or code segments to perform the tasks may be stored in a non-transitory computer-readable medium such as a storage medium. Processors may perform one or more of the described tasks.

Components, functional or otherwise, shown in the figures and/or discussed herein as being connected, coupled (e.g., communicatively coupled), or communicating with each other are operably coupled. That is, they may be directly or indirectly, wired and/or wirelessly, connected to enable signal transmission between them.

Having described several example configurations, various modifications, alternative constructions, and equivalents may be used. For example, the above elements may be components of a larger system, wherein other rules may take precedence over or otherwise modify the application of the disclosure. Also, a number of operations may be undertaken before, during, or after the above elements are considered. Accordingly, the above description does not bound the scope of the claims.

Unless otherwise indicated, “about” and/or “approximately” as used herein when referring to a measurable value such as an amount, a temporal duration, and the like, encompasses variations of ±20% or ±10%, ±5%, or ±0.1% from the specified value, as appropriate in the context of the systems, devices, circuits, methods, and other implementations described herein. Unless otherwise indicated, “substantially” as used herein when referring to a measurable value such as an amount, a temporal duration, a physical attribute (such as frequency), and the like, also encompasses variations of ±20% or ±10%. ±5%. or ±0.1% from the specified value, as appropriate in the context of the systems, devices, circuits, methods, and other implementations described herein.

Further, more than one invention may be disclosed.

1. A method of controlling a solid precursor vapor source, comprising:
providing a carrier gas to a sublimation vessel containing a solid precursor material, wherein a temperature of the carrier gas is controlled with a carrier gas thermal device prior to entering the sublimation vessel via an inlet area and the carrier gas flows parallel to a surface of the precursor material;
measuring a temperature of a vapor exiting the sublimation vessel via an outlet area; and
controlling the temperature of the carrier gas with the carrier gas thermal device based at least in part on the temperature of the vapor exiting the sublimation vessel.

2. The method of claim 1 further confining the carrier gas flow to an open space above the surface of the precursor bed extending at least 1 mm but not more than 100 mm above the surface of the precursor bed.

3. The method of claim 1 further comprising setting a pressure inside the sublimation vessel.

4. The method of claim 3 wherein setting the pressure inside the sublimation vessel is based at least in part on the temperature of the vapor exiting the sublimation vessel.

5. The method of claim 1 further comprising producing one or more flow paths above the surface of the solid precursor material, for the carrier gas, using one or more baffles disposed above and inside the solid precursor material.

6. The method of claim 5 wherein the carrier gas flow velocity through the multiple flow paths is proportional to the length of the respective path from the inlet area to the outlet area.

7. The method of claim 1 wherein controlling the temperature of the carrier gas includes determining a sublimation temperature of the solid precursor material and increasing the temperature of the carrier gas based on the temperature of the vapor exiting the sublimation vessel being below the sublimation temperature of the solid precursor material, and decreasing the temperature of the carrier gas based on the temperature of the vapor exiting the sublimation vessel being above the sublimation temperature of the solid precursor material.

8. The method of claim 7 wherein determining the temperature of the solid precursor material at the vessel outlet includes determining a pressure inside the sublimation vessel.

9. The method of claim 1 further comprising disposing a thermally isolating shroud around at least a portion of the sublimation vessel.

10. An apparatus, comprising:
a sublimation vessel containing a solid precursor material;
an inlet port to admit a carrier gas to the sublimation vessel;
an outlet port to extract a vapor of a precursor from the sublimation vessel;
a carrier gas thermal device configured to control a temperature of a carrier gas entering the sublimation vessel;
at least one baffle disposed in the sublimation vessel and configured to produce one or more flow paths above the surface of the solid precursor material;
at least one temperature sensor configured to measure a temperature of a carrier gas at the inlet port of the sublimation vessel;
at least one temperature sensor configured to measure a temperature the precursor bed at the outlet port of the sublimation vessel; and
an apparatus control computer communicatively coupled to the carrier gas thermal device and the at least one temperature sensor, and configured to control the temperature of the carrier gas with the carrier gas thermal device based at least in part on the temperature of the vapor exiting the sublimation vessel.

11. The apparatus of claim 10 further comprising a pressure controller communicatively coupled to the apparatus controller, wherein the apparatus controller is configured to set a pressure inside the sublimation vessel with the pressure controller.

12. The apparatus of claim 10 wherein the apparatus controller is configured to set the pressure inside the sublimation vessel with the pressure controller based on the sublimation temperature of the solid precursor material.

13. The apparatus of claim 10 further comprising a mass flow controller communicatively coupled to the apparatus controller, wherein the apparatus controller is configured to set a flow of the carrier gas into the sublimation vessel with the mass flow controller.

14. The apparatus of claim 10 wherein the sublimation vessel is configured to confine the carrier gas to a flow path that extends not less than 1 millimeter above the surface of the precursor bed and extends not more than 100 millimeters above the surface of the precursor bed.

15. The apparatus of claim 10 further comprising a thermally isolating shroud disposed around at least a portion of the sublimation vessel.
